(19) United States
(12) Patent Application Publication
(10) Pub. No.: US 2010/0083073 A1
(43) Pub. Date: Apr. 1, 2010

(54) Data processing apparatus, memory controlling circuit, and memory controlling method

(75) Inventor: Youji Terauchi, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC Electronics Corporation, Kawasaki (JP)

(21) Appl. No.: 12/585,493

(22) Filed: Sep. 16, 2009

(30) Foreign Application Priority Data
Sep. 26, 2008 (JP) 2008-248560

(51) Int. Cl. G06F 12/00; H03M 13/09; H03M 13/05; G06F 12/02; G06F 11/10

(52) U.S. Cl. 714/763; 711/156; 714/799; 711/103; 711/E12.001; 711/E12.008; 714/E11.032

(57) ABSTRACT

A data processing apparatus includes a memory, an additional bit generating unit which generates an additional bit to be added to write expectation values, on a basis of the write expectation values to be written respectively to designated addresses in the memory, the additional bit and the write expectation values being supplied to the memory as write data and stored respectively in memory cells at the addresses, and a write state judging unit which reads stored data retained in the memory cells at the addresses and judges a write state of the memory cells.

### INCORPORATION BY REFERENCE

This application is based upon and claims the benefit of priority from Japanese Patent Application No. 2008-248560 which was filed on Sep. 26, 2008, the disclosure of which is incorporated herein in its entirety by reference.

### BACKGROUND OF THE INVENTION

1. Field of the Invention

The present invention relates to a data processing apparatus, and a memory controlling circuit and a memory controlling method for a memory incorporated in the data processing apparatus.

2. Description of Related Art

In recent years, there has been an increasing number of data processing apparatuses each equipped with a non-volatile memory such as a flash memory. A flash memory allows programs to be rewritten therein after being embedded in an apparatus. For this reason, an apparatus equipped with a flash memory can flexibly deal with a specification change, a software change when a trouble occurs, and the like. Moreover, it is easy to develop models by software changes while using the same hardware.

Meanwhile, in the case of an integrated circuit on which a microcomputer and a flash memory are mounted in a single chip, it is possible to rewrite an incorporated flash memory by a user program. It is therefore possible to achieve an electrically erasable and programmable read only memory (EEPROM) emulation in which the incorporated flash memory is used as if it is an EEPROM. By utilizing this function, it is possible to retain and rewrite data without externally connecting an EEPROM, and thereby to achieve cost reduction, space saving, and functional improvement of apparatuses.

Such a data processing apparatus provided with a memory and operated by software sometimes writes data in a memory cell at an unintended address due to a hardware failure, a programming error, or the like. If data has been already written in that memory cell, then contents saved in the memory are rewritten, which significantly affects the system.

Methods of preventing a write error are disclosed in, for example, JP-A-2004-062978, JP-A-2004-039127, and the like. In these methods, flags indicating, for example, a write inhibit for each block are set in a dedicated sector in a flash memory. It is usual to set protection by hardware on the basis of the flags thus set in order to avoid occurrence of rewrite. Therefore, a write command is cancelled if an address of a data write destination is included in a write-prohibited block.

Meanwhile, WO01/061503 discloses a method of preventing occurrence of a write error that occurs in an attempt to change non-executable data.

### SUMMARY

However, the present inventor has recognized the following point. Namely, in the methods of preventing the write error disclosed in JP-A-2004-062978 and JP-A-2004-039127, a write is executed if an unintended write destination is included in a write-permitted block. For example, in a case of sequentially writing data while sequentially shifting the write address, data to be written next may be overwritten on a memory cell in which a write has been just finished, if the sequential shifting of the write addresses in the memory stops for some reason. Meanwhile, in the method disclosed in WO01/061503, there are cases where data can be and cannot be written, depending on a combination of write target data and original data at a corresponding write address. Accordingly, it is not possible to prevent a data write to a memory cell at an unintended address.

The present invention provides a data processing apparatus, a memory control circuit, and a memory controlling method for preventing an erroneous data write to a memory region in which data have been written already.

The present invention seeks to solve one or more of the above problems, or to improve upon those problems at least in part.

In one exemplary embodiment, a data processing apparatus includes a memory, an additional bit generating unit which generates an additional bit to be added to write expectation values, on a basis of the write expectation values to be written respectively to designated addresses in the memory, the additional bit and the write expectation values being supplied to the memory as write data and stored respectively in memory cells at the addresses, and a write state judging unit which reads stored data retained in the memory cells at the addresses and judges a write state of the memory cells.

In another exemplary embodiment, a memory control circuit includes an additional bit generating unit which generates an additional bit to be added to write expectation values, on a basis of the write expectation values to be written respectively to designated addresses in a memory, the additional bit and the write expectation values being supplied to the memory as write data and stored respectively in memory cells at the addresses, and a write state judging unit which reads stored data retained in the memory cells at the addresses and judges a write state of each of the memory cells.

In yet another exemplary embodiment, a memory controlling method includes initially setting a first value indicating an erased state, in all memory cells included in a memory, generating an additional bit to be added to write expectation values on a basis of the write expectation values to be written respectively to designated addresses in the memory, supplying the write expectation values and the additional bit to the memory, storing the write expectation values and the additional bit respectively in memory cells at the addresses, and reading stored data retained in the memory cells at the addresses, and judging a write state of the memory cells prior to the storing.

According to the present invention, it is possible to provide a data processing apparatus, a memory control circuit, and a memory controlling method for preventing an erroneous data write to a memory region in which data have been written already.

### BRIEF DESCRIPTION OF THE DRAWINGS

The above and other purposes, advantages and features of the present invention will become more apparent from the following description of a certain exemplary embodiment taken in conjunction with the accompanying drawings in which:

FIG. 1 is a block diagram showing a configuration of a data processing apparatus 10 according to a first exemplary embodiment of the present invention;

FIG. 2 is a block diagram showing a configuration of a flash control unit 14 according to the first exemplary embodiment of the present invention;

FIG. 3 is a diagram showing a configuration of a write control unit 25 according to the first exemplary embodiment of the present invention;

FIG. 4 is a diagram showing a configuration example of the write control unit 25 according to the first exemplary embodiment of the present invention;

FIG. 5A is a diagram showing a configuration example of the write control unit 25 according to the first exemplary embodiment of the present invention;

FIG. 5B is a diagram showing a configuration example of an additional bit generating unit 31 according to the first exemplary embodiment of the present invention;

FIG. 6 is a diagram showing a configuration example of the write control unit 25 according to the first exemplary embodiment of the present invention; and

FIG. 7 is a diagram showing operations of the flash control unit 14 according to the first exemplary embodiment of the present invention.

### DETAILED DESCRIPTION OF THE EXEMPLARY EMBODIMENTS

The invention will now be described herein with reference to an illustrative exemplary embodiment. Those skilled in the art will recognize that many alternative embodiments can be accomplished using the knowledge of the present invention, and that the invention is not limited to the exemplary embodiment illustrated for explanatory purposes.

### First Exemplary Embodiment

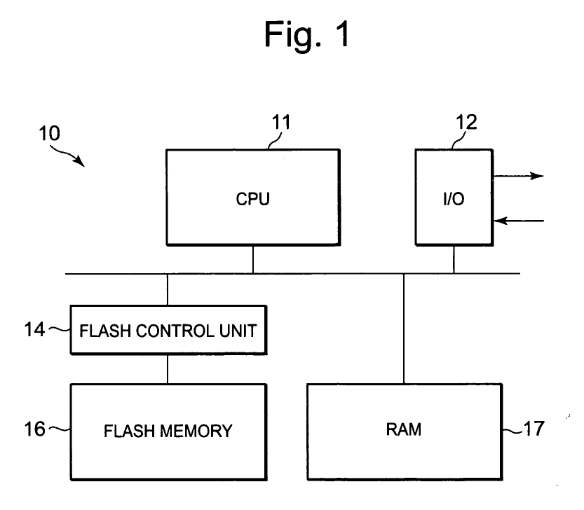

FIG. 1 is a block diagram showing a configuration of a data processing apparatus 10 according to a first exemplary embodiment of the present invention. The data processing apparatus 10 includes a central processing unit (CPU) 11, an input-output unit (I/O) 12, a flash control unit 14, a flash memory 16, and a random access memory (RAM) 17. The CPU 11 executes a program code stored in the flash memory 16. Moreover, the CPU 11 starts the flash control unit 14 and writes data into the flash memory 16. The input-output unit 12 retrieves data from outside, and outputs processed data to the outside. The flash control unit 14 controls data write and read to and from the flash memory 16. The RAM 17 is used as a work area for storing temporary data and the like.

The CPU 11, the input-output unit 12, the flash control unit 14, and the RAM 17 exchange data through a bus. Here, the CPU 11 designates write data to the flash memory 16 on a 32-bit basis, for example. The flash memory 16 has a bit width of, for example, 33 bits, which is wider than the width of that data. Specifically, the flash control unit 14 writes the data in the flash memory 16 while using the 33-bit width as a write unit, and reads data out of the flash memory 16 according to that bit width. Meanwhile, data which is frequently rewritten is not stored in the flash memory 16. That is, the flash memory 16 stores data such as program codes, which are not overwritten.

Here, the flash memory 16 being a non-volatile memory is shown as an example of a memory for preventing a write error. However, the memory can be an EEPROM or other memories. Moreover, the flash memory may include those each having a high output voltage in the erased state and those each having a low output voltage in the erased state. Here, the case of the flash memory configured to have a higher output voltage when data is erased is shown as an example. Therefore, the flash memory 16 will be explained as one whose memory cell indicates “1” when it is in the erased state, and “0” when it is in the written state.

Specifically, when data indicating “0” is written in the memory cell in the erased state indicated by “1,” the memory cell turns to the written state indicated by “0.” In contrast, an attempt to write data indicating “1” into the memory cell in the written state “0” does not change the state of the memory cell. In order to bring the memory cell into the erased state “1,” all the bits on the block basis need to be brought into the erased state by an erasing operation.

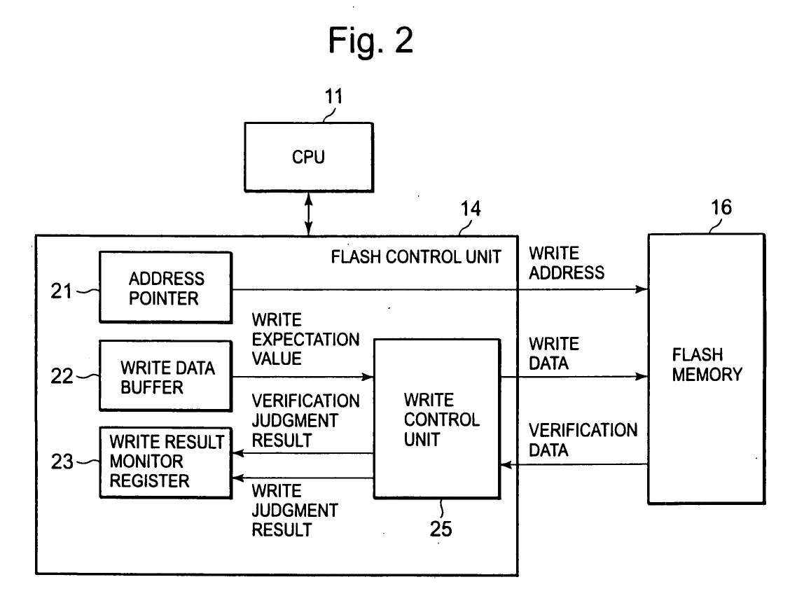

As shown in FIG. 2, the flash control unit 14 includes an address pointer 21, a write data buffer 22, a write result monitor register 23, and a write control unit 25. Here, illustration and explanation of parts related to a read operation and an erasing operation will be omitted in order to explain a write operation of the flash control unit 14.

The address pointer 21 retains write addresses of the flash memory 16 instructed by the CPU 11, and supplies the addresses to the flash memory 16. The write data buffer 22 retains write expectation values to be written in the flash memory 16, which is instructed by the CPU 11, and supplies the values to the write control unit 25. The write result monitor register 23 retains a verification judgment result and a write judgment result which are outputted from the write control unit 25, such that the CPU 11 can monitor the results. The write control unit 25 supplies write data provided, on the basis of the write expectation value supplied from the write data buffer 22, with an additional bit to the flash memory 16. Moreover, the write control unit 25 retrieves verification data from the flash memory 16, and supplies a verification judgment result and a write judgment result to the write result monitor register 23. The verification judgment result indicates whether or not the data is successfully written in the addresses indicated by the address pointer 21. The write judgment result indicates whether or not the address is in the written state. The operation of each of the address pointer 21, the write data buffer 22, the write result monitor register 23, and the write control unit 25 is controlled by an unillustrated sequencer of the flash control unit 14.

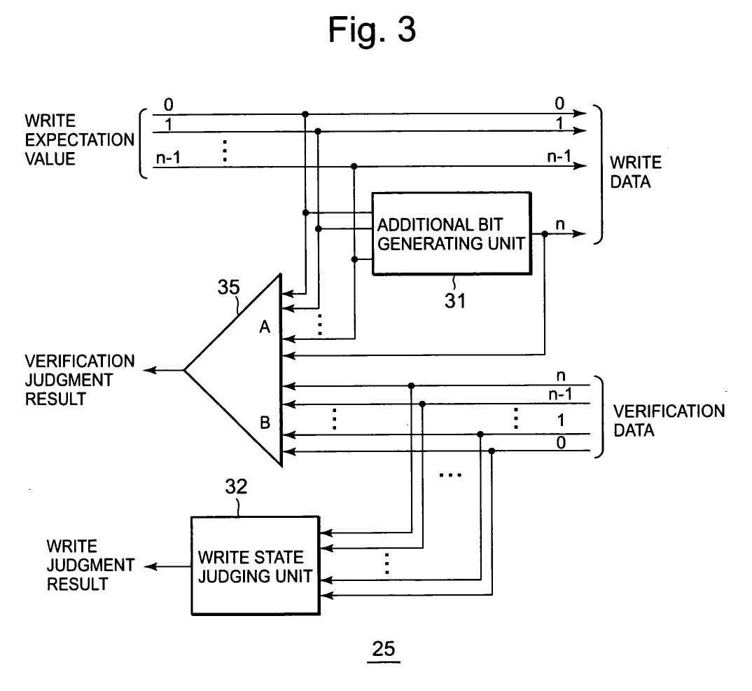

As shown in FIG. 3, the write control unit 25 includes an additional bit generating unit 31, a write state judging unit 32, and a data comparator 35. The write expected value supplied from the write data buffer 22 includes n bit data ranging from bit 0 to bit n−1. The write expectation values are supplied to the flash memory 16 as the bit 0 to the bit n−1 of write data, and are also supplied to the data comparator 35 and the additional bit generating unit 31. The additional bit generating unit 31 generates a bit n of the write data on the basis of the write expectation values, and supplies it to the flash memory 16 and the data comparator 35. Thus, the write data having n+1 bits is supplied to the flash memory 16.

The flash memory 16 has a bit width which allows n+1 bit data to be written at a time. In writing the data in the flash memory 16, the data is read out of the flash memory 16 after write and judgment is made as to whether the data matches the write expectation values. This operation is called “verification”. The verification data being the data read out of the flash memory 16 is the data having n+1 bits including the bit 0 to bit n.

The verification data having n+1 bits is inputted to the data comparator 35 and compared with the write expectation values. The write operation is completed when the verification data matches the write expectation values. In the case of mismatch, it is usual for the flash memory to repeat rewrite for a predetermined number of times. Here, for a simple explanation, it is assumed that rewrite is not performed and an error process is executed after mismatch occurs, and thus it is determined that write has been failed.

In the present invention, a judgment is made as to whether the memory cell indicated by the write address is in the written state, by utilizing this verifying operation before data write. Specifically, when there is an instruction for a data write, the write control unit 25 firstly performs verification before the write and reads the data stored in the memory cells of the flash memory 16 and indicated by the write addresses. The write state judging unit 32 outputs a write judgment result indicating that data has been written, upon detection of the bit in the written state “0” in the read verification data or outputs a write judgment result indicating that the data is writable (not written), when all the bits are in the erased state “1.”

The write judgment result indicating that the data has been written is equivalent to issuance of an instruction to overwrite new data in the written memory cells. If the write expectation values have “1” for all of its bits and do not have the additional bit, then the write expectation values are the same as data in the erased state and are therefore indiscernible. In the present invention, even when all the bits of the write expectation values are “1” and thus are the same as the erased state, the data is discernible by setting the additional bit to the written state. Specifically, even if all the bits corresponding to the write expectation values of the read data are in the erased state, presence of the additional bit in the written state indicates that data having “1” for all of its bits is stored in the addresses. In contrast, all the bits including the additional bit being in the erased state indicates that the addresses are in the erased state.

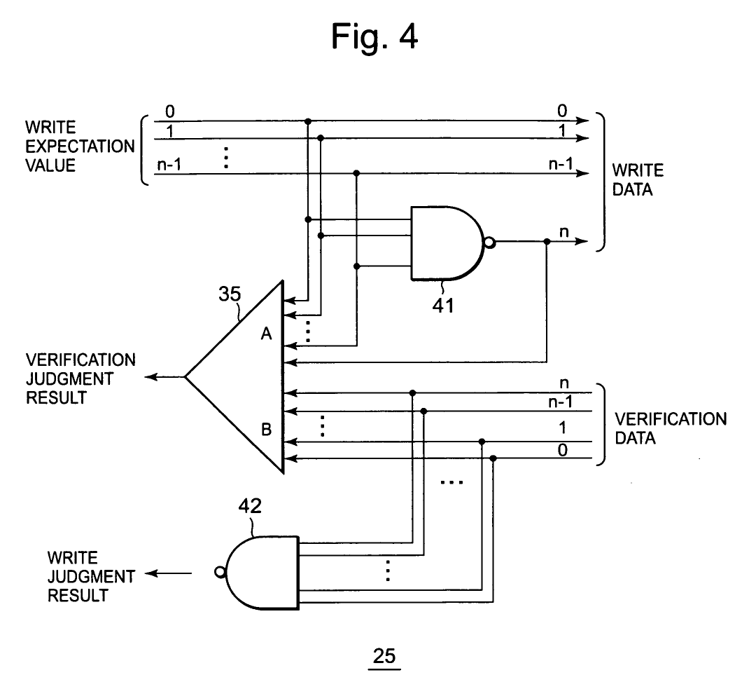

As shown in FIG. 4, the additional bit generating unit 31 may be a NAND circuit 41. The NAND circuit 41 outputs “0” as the additional bit n when all the bits in the write expectation values are “1.” When any of the bits in the write expectation values is “0,” the NAND circuit 41 outputs “1” as the additional bit n. Thus, “0” is outputted in any case of the write expectation values, as long as at least one bit out of n+1 bits of the write data is in the written state.

As shown in FIG. 4, the write state judging unit 32 may be a NAND circuit 42. When at least one bit out of n+1 bits of the verification data read out of the flash memory 16 indicates the written state “0,” the NAND circuit 42 outputs, as the write judgment result, “1” indicating that data has been written. When all the bits in the verification data are in the erased state “1,” the NAND circuit 42 outputs, as the write judgment result, “0” indicating that data has not been written.

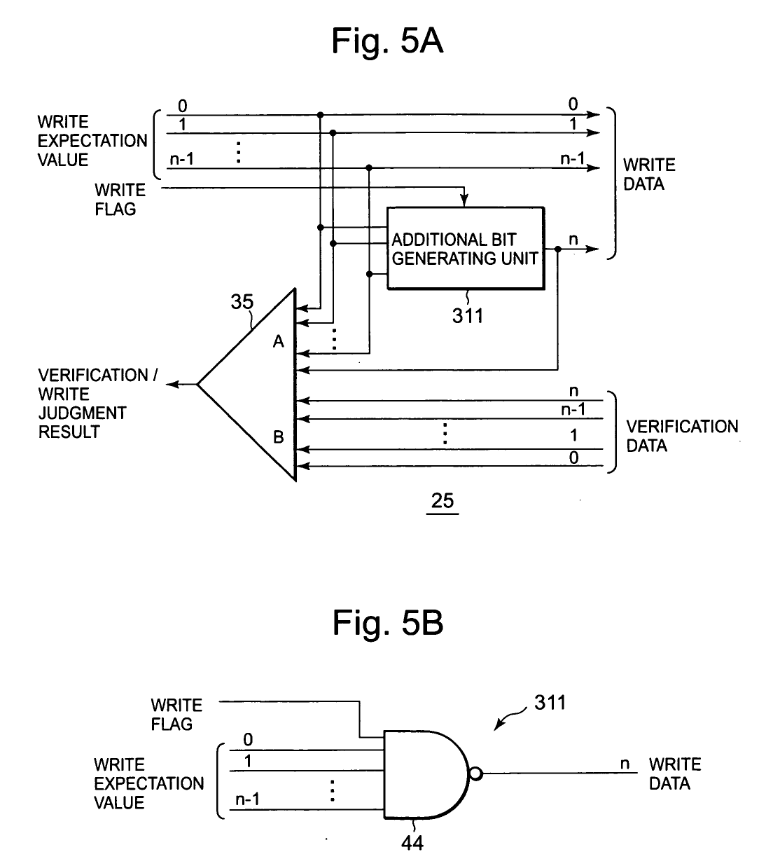

Meanwhile, as shown in FIG. 5A, the additional bit generating unit 31 may be an additional bit generating unit 311 which changes an output value on the basis of a write flag indicating whether or not it has been verified before a write (i.e., a verification before write). As shown in FIG. 5B, the additional bit generating unit 311 can be implemented by a NAND circuit 44. In the case of “1,” the write flag represents the data write operation or the verifying operation after write whereas, in the case of “0,” the write flag represents the verifying operation before write. When the write flag is “1” and all the bits of the write expectation values are “1,” the NAND circuit 44 outputs “0” and supplies, to the flash memory 16, the additional bit n of the write data that represents the written state. Meanwhile, at the time of verification after write, the output from the NAND circuit 44 is supplied to the data comparator 25, and used for judging whether or not data is in the written state. When the write flag is “0,” the NAND circuit 44 outputs “1” to the data comparator 25 regardless of what the write expectation values are. Therefore, the output from the NAND circuit 44 is used for judging whether or not the additional bit n of the verification data is in the erased state.

As described above, by changing the output from the additional bit generating unit 311 between verification before write and verification during or after write, the data comparator 35 can also serve as the write state judging unit 32. Specifically, at the time of verification before write, the data showing that all the bits are in the erased state is set in the write buffer 22. As the write state judging unit 32, the data comparator 35 judges whether or not the memory cells at the set addresses are the memory cells which have already been set with the write expectation values (storing data). In a verification operation after write, the write expectation values are stored in the write data buffer 22. The data comparator 35 judges whether the write of the write expectation values and the additional bit in the memory cells has succeeded. As the data comparator 35 operates in lieu of the write state judging unit 32, it is not necessary to provide the write state judging unit 32 separately.

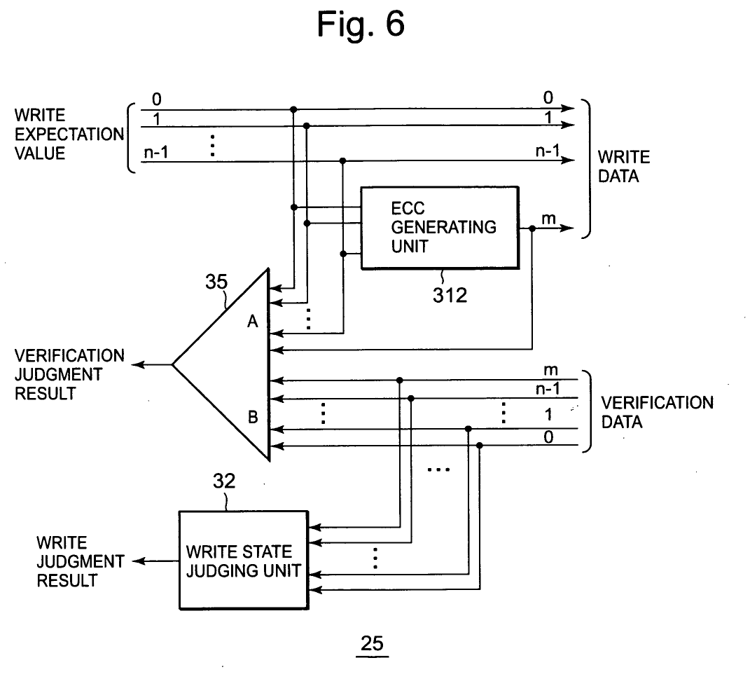

Meanwhile, as shown in FIG. 6, it is also possible to provide the write expectation values with redundancy by utilizing additional bits so as to improve reliability. Here, the write data is generated by providing the write expectation values with multiple-bit error correction codes. Even when all the bits in the write expectation values are “1,” if some bits of the multiple additional bits are “0,” then it is possible to judge whether the data having “1” for all the bits is stored in the corresponding address, or the address is in the erased state and no data are written therein. In the case of the error correction codes, error detecting and correcting processes are executed at the time of read from the flash memory 16. Explanation thereof will be omitted herein. It is possible to add one bit of a parity bit instead of the multiple additional bits. In that case, by using an even parity, it is possible to judge that the address is in the write state as the party bit becomes “0” even when all the bits in the write expectation values are “1.” Note that the write expectation values generally have a bit width of 2ⁿ bits, which is mostly a bit width equivalent to 8 bits, 16 bits, or 32 bits.

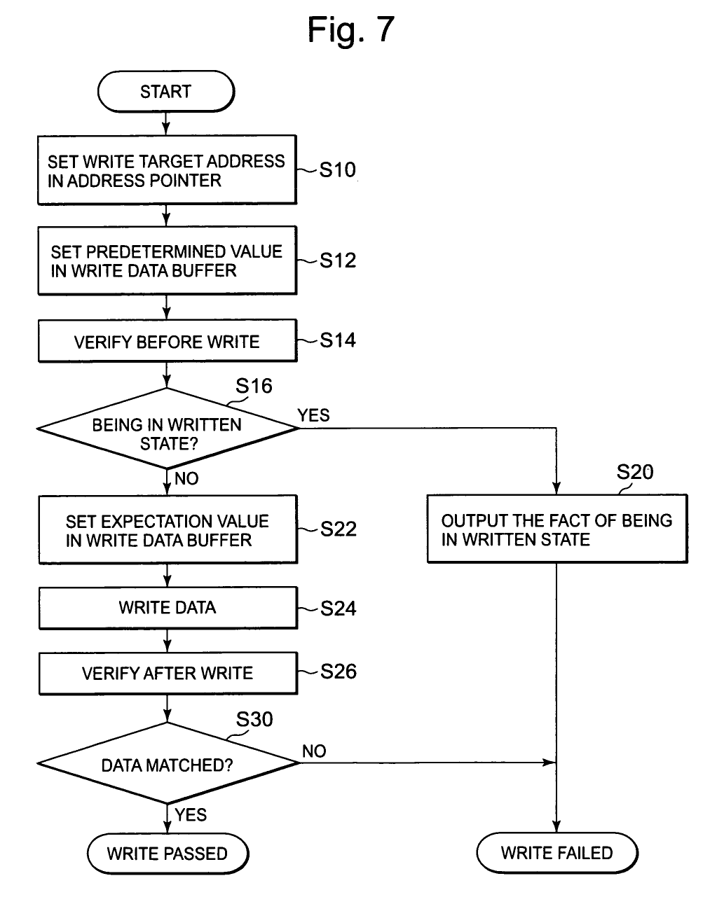

Next, operations of the flash control unit 14 will be described with reference to FIG. 7.

At the time of writing data in the flash memory 16, a destination in which the data is to be written, i.e. a write target address, is set in the address pointer 21 (step S10). The address pointer 21 supplies the write address to the flash memory 16.

A predetermined value for executing a verification before write is set in the write data buffer 22 (step S12). As shown in FIG. 4 and FIG. 6, the value to be set is not limited if the data comparator 35 is not used for judging the write state. When the data comparator 35 judges the write state as shown in FIG. 5A, the value to be set in the write data buffer 22 must be the value that reflects the erased state of the flash memory 16. Here, the memory cell in the erased state indicates “1.” Accordingly, the data having “1” for all the bits including the additional bit is set. Next, in order to perform the verification before write, the verification data is read out from the flash memory 16 to the write state judging unit 32 and to the data comparator 35 (step S14). The write state judging unit 32 judges the write state based on whether or not all the bits in the verification data are “1.”

If any of the bits in the verification data is “0,” then the write state judging unit 32 judges that the address is in the written state and is retaining a certain value (step S16—YES), and then outputs the write judgment result indicating “written” (step S20). The CPU 11 is notified of the write judgment result outputted from the write control unit 25 through the write result monitor register 23. A hardware failure or a software bug is suspected from the fact that the instruction to write data in the written region has been given. Accordingly, it is preferable that the CPU 11 performs exception handling.

When all the bits in the verification data are “1,” the write judgment unit 32 judges that no data has been written yet in the address and outputs the write judgment result indicating “writable” (step S16—NO).

When the memory cells at the designated addresses are confirmed to be writable, the write expectation values are set in the write data buffer 22 (step S22). The additional bit generating unit 31 generates the additional bit data based on the write expectation values, and the write data is supplied to the flash memory 16. When all the bits in the write expectation values are “1,” the additional bit data includes the bit indicating “0.” Thereafter, the write data is written in the memory cells which are designated by the address pointer 21 (step S24).

When the write is completed, the data is read out of the flash memory 16 and the verification after write is executed to check whether the write data has been properly written (step S26). The data comparator 35 compares the write expectation values including the additional bit with the verification data, and outputs the verification judgment result. The write control unit 25 terminates the write operation upon confirmation that the write expectation values including the additional bit matches the verification data (step S30—YES). When the write expectation values including the additional bit do not match the verification data (step S30—NO), the write control unit 25 outputs the verification judgment result representing a write failure and then terminates the write operation. Here, data write to a flash memory often involves several sessions of retrials which will be omitted herein.

In the above description, the value of the additional bit data is determined based on the write expectation values. Instead, it is also possible to define the additional bit as a bit simply indicating “write”. Specifically, it is possible to perform the write operation by setting the additional bit to “0” regardless of the write expectation values. However, it is necessary to pay attention that the memory cell corresponding to the additional bit is set to the written state every time data write is performed. Meanwhile, when the write expectation values are data including a redundant bit such as an error correction code, it is also possible to employ a configuration in which an additional bit indicating that data has been written is added. It is possible to detect presence of the written states, without being influenced by modes of the error correction codes and the like.

The above-described write control may be realized by software. The present invention is preferably applied to a non-volatile memory such as a flash memory but is not limited only to the non-volatile memory. It is also possible to apply the present invention to a RAM that prohibits data overwrite. In that case, it is preferable to provide a mechanism for temporarily aborting a function to prohibit overwrite for initial setting of the memory.

As described above, according to the present invention, it is possible to judge whether or not data has been written, irrespective of what values are included in data written in a memory, and to prevent overwrite of other data on the written data.

Although the invention has been described above in connection with the exemplary embodiment thereof, it will be appreciated by those skilled in the art that that exemplary embodiment is provided solely for illustrating the invention, and should not be relied upon to construe the appended claims in a limiting sense.

Further, it is noted that, notwithstanding any claim amendments made hereafter, applicant's intent is to encompass equivalents all claim elements, even if amended later during prosecution.

What is claimed is:

1. A data processing apparatus, comprising:
a memory;
an additional bit generating unit which generates an additional bit to be added to write expectation values, on a basis of the write expectation values to be written respectively to designated addresses in the memory, the additional bit and the write expectation values being supplied to the memory as write data and stored respectively in memory cells at the addresses; and
a write state judging unit which reads stored data retained in the memory cells at the addresses and judges a write state of the memory cells.

2. The data processing apparatus according to claim 1,
wherein each of the memory cells is set to a first value representing an erased state, at a time of initial setting, and retains any one of the first value and a second value which represents a write state and is obtained by inverting the first value, and
wherein the write state judging unit judges that the memory cells have been written, when any of the bits included in the stored data indicates the second value.

3. The data processing apparatus according to claim 2,
wherein the write state judging unit judges the write state before the write data is stored in the memory cells at the addresses, and aborts the storing of the write data when the memory cells are judged to be already written.

4. The data processing apparatus according to claim 2,
wherein the additional bit generating unit generates the additional bit including the second value, in a case where values of all the bits in the write expectation values are the first value.

5. The data processing apparatus according to claim 2,
wherein the additional bit generating unit generates the additional bit including the second value correspondingly to all the write expectation values.

6. The data processing apparatus according to claim 2,
wherein the additional bit generating unit generates the additional bit including an error detection code for the write expectation values.

7. The data processing apparatus according to claim 2,
wherein the additional bit generating unit generates the additional bit including the second value in a case where values of all the bits in the write expectation values including an error correction code are the first value.

8. The data processing apparatus according to claim 1,
wherein the memory comprises a flash memory having a bit width obtained by adding a bit width of the additional bit to a bit width of the write expectation values.

9. A memory control circuit, comprising:
an additional bit generating unit which generates an additional bit to be added to write expectation values, on a basis of the write expectation values to be written respectively to designated addresses in a memory, the additional bit and the write expectation values being supplied to the memory as write data and stored respectively in memory cells at the addresses; and
a write state judging unit which reads stored data retained in the memory cells at the addresses and judges a write state of each of the memory cells.

10. The memory control circuit according to claim 9,
wherein each of the memory cells is set to a first value representing an erased state, at a time of initial setting and retains any one of the first value and a second value which represents a write state and is obtained by inverting the first value, and
the write state judging unit judges that the memory cells have been written, when the stored data includes a bit of the second value.

11. The memory control circuit according to claim 10,
wherein the write state judging unit judges the write state before the write data is stored in the memory cells at the addresses and aborts the storing of the write data when the memory cells are judged to be already written.

12. The memory control circuit according to claim 10,
wherein the additional bit generating unit generates the additional bit including the second value, in a case where values of all the bits in the write expectation values are the first value.

13. The memory control circuit according to claim 10,
wherein the additional bit generating unit generates the additional bit including the second value correspondingly to all the write expectation values.

14. The memory control circuit according to claim 10,
wherein the additional bit generating unit generates the additional bit including an error detection code for the write expectation values.

15. The memory control circuit according to claim 10,
wherein the additional bit generating unit generates the additional bit including the second value in a case where values of all the bits in the write expectation values including an error correction code are the first value.

16. A memory controlling method, comprising:
initially setting a first value indicating an erased state, in all memory cells included in a memory;
generating an additional bit to be added to write expectation values on a basis of the write expectation values to be written respectively to designated addresses in the memory;
supplying the write expectation values and the additional bit to the memory;
storing the write expectation values and the additional bit respectively in memory cells at the addresses; and
reading stored data retained in the memory cells at the addresses, and judging a write state of the memory cells prior to the storing.

17. The memory controlling method according to claim 16,
wherein the judging includes judging that the memory cells have been written, when any of the bits included in the stored data indicates a second value representing a write state and is obtained by inverting the first value.

18. The memory controlling method according to claim 17,
wherein, if it is judged, in the judging, that the memory cells have been written, the storing includes:
supplying the write expectation values and the additional bit to the memory without storing the write expectation values and the additional bit in the memory cells at the addresses.

19. The memory controlling method according to claim 17,
wherein the generating includes:
generating the additional bit including the second value, in a case where values of all the bits in the write expectation values are the first value.

20. The memory controlling method according to claim 17,
wherein the generating includes:
generating the additional bit including the second value correspondingly to all the write expectation values.

21. The memory controlling method according to claim 17,
wherein the generating includes:
generating the additional bit including an error detection code for the write expectation values.

22. The memory controlling method according to claim 17,
wherein the generating includes:
generating the additional bit including the second value in a case where values of all the bits in the write expectation values including an error correction code are the first value.
